(19) United States
(12) Patent Application Publication
(10) Pub. No.: US 2025/0316896 A1
(43) Pub. Date: Oct. 9, 2025

(54) ELECTRONIC DEVICE AND SIGNAL TRANSCEIVING MODULE

(71) Applicant: KalkuTek INC., Taipei (TW)

(72) Inventors: Mike Chun-Hung Wang, Taipei (TW); Chih-Yin Wei, Taipei (TW); Hsiao-Ting Huang, Taipei (TW)

(73) Assignee: KalkuTek INC., Taipei (TW)

(21) Appl. No.: 18/630,998

(22) Filed: Apr. 9, 2024

(51) Int. Cl. H01Q 1/46; H01Q 1/22; H01R 13/6581

(52) U.S. Cl. CPC H01Q 1/46; H01Q 1/22; H01R 13/6581

(57) ABSTRACT

An electronic device includes a casing and a signal transceiving module. The signal transceiving module is disposed in the casing. The signal transceiving module includes a connector, a circuit board, and a signal transceiver. The connector has a connecting hole and a signal feed-in hole. The connecting hole is formed on a first side of the connector and exposed from a side of the casing. The signal feed-in hole is formed on a second side of the connector. The first side is adjacent to the second side. The circuit board is disposed at a side of the connector. The signal transceiver is connected to the circuit board and aligned with the signal feed-in hole. The signal transceiver feeds signals into the connector through the signal feed-in hole and the signals are radiated out of the connector through the connecting hole.

### BACKGROUND OF THE INVENTION

### 1. Field of the Invention

The invention relates to an electronic device and a signal transceiving module and, more particularly, to a signal transceiving module integrating a signal transceiver onto a connector and an electronic device equipped with the signal transceiving module.

### 2. Description of the Prior Art

An antenna or radar has been often used in an electronic device to perform wireless operation. At present, the electronic device is becoming thinner and thinner in design, such that there is not much space left inside the electronic device for arranging the antenna or radar. Therefore, how to arrange the antenna or radar in the electronic device without increasing the size of the electronic device has become a significant design issue.

### SUMMARY OF THE INVENTION

The invention provides a signal transceiving module integrating a signal transceiver onto a connector and an electronic device equipped with the signal transceiving module, so as to solve the aforesaid problems.

According to an embodiment of the invention, an electronic device comprises a casing and a signal transceiving module. The signal transceiving module is disposed in the casing. The signal transceiving module comprises a connector, a circuit board, and a signal transceiver. The connector has a connecting hole and a signal feed-in hole. The connecting hole is formed on a first side of the connector and exposed from a side of the casing. The signal feed-in hole is formed on a second side of the connector. The first side is adjacent to the second side. The circuit board is disposed at a side of the connector. The signal transceiver is connected to the circuit board and aligned with the signal feed-in hole. The signal transceiver feeds signals into the connector through the signal feed-in hole and the signals are radiated out of the connector through the connecting hole.

According to another embodiment of the invention, a signal transceiving module comprises a connector, a circuit board and a signal transceiver. The connector has a connecting hole and a signal feed-in hole. The connecting hole is formed on a first side of the connector. The signal feed-in hole is formed on a second side of the connector. The first side is adjacent to the second side. The circuit board is disposed at a side of the connector. The signal transceiver is connected to the circuit board and aligned with the signal feed-in hole. The signal transceiver feeds signals into the connector through the signal feed-in hole and the signals are radiated out of the connector through the connecting hole.

As mentioned in the above, the invention integrates the signal transceiver (e.g. antenna, radar, etc.) onto the connector. The connector has the connecting hole and the signal feed-in hole, and the signal transceiver is aligned with the signal feed-in hole, such that the signal transceiver can feed signals into the connector through the signal feed-in hole and the signals can be radiated out of the connector through the connecting hole. Accordingly, the signal transceiver can be disposed at the space around the connector to avoid increasing the size of the electronic device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective view illustrating an electronic device according to an embodiment of the invention.

FIG. 2 is a perspective view illustrating a signal transceiving module shown in FIG. 1.

FIG. 3 is a perspective view illustrating a connector shown in FIG. 2.

FIG. 4 is a sectional view illustrating the signal transceiving module shown in FIG. 2.

### DETAILED DESCRIPTION

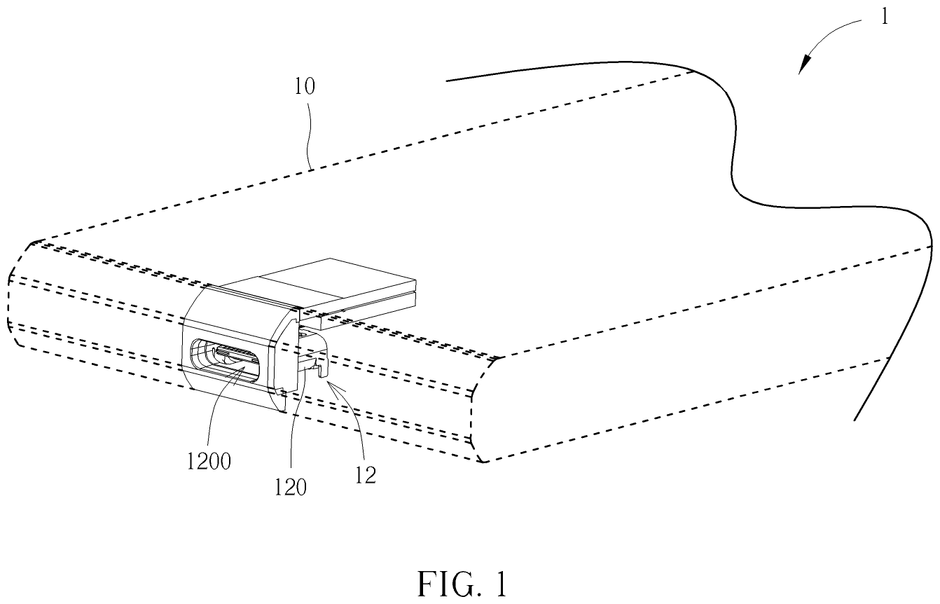

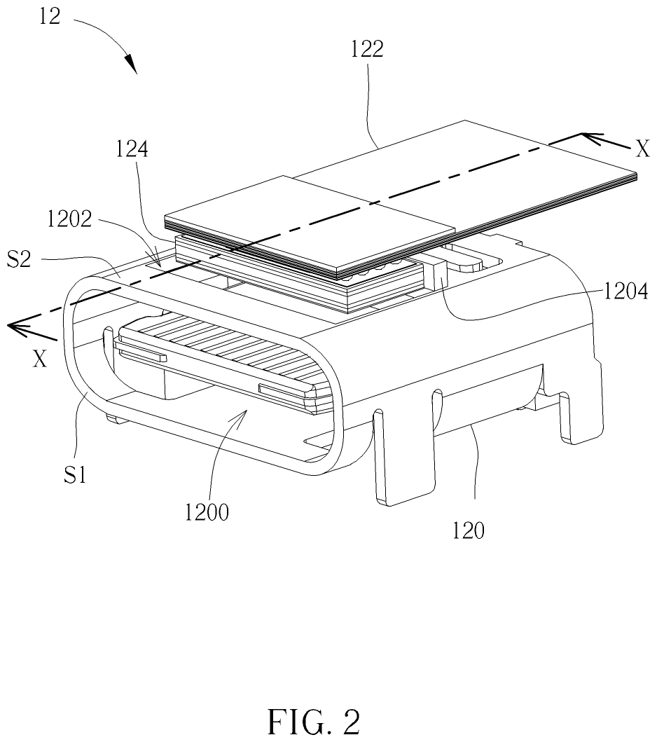

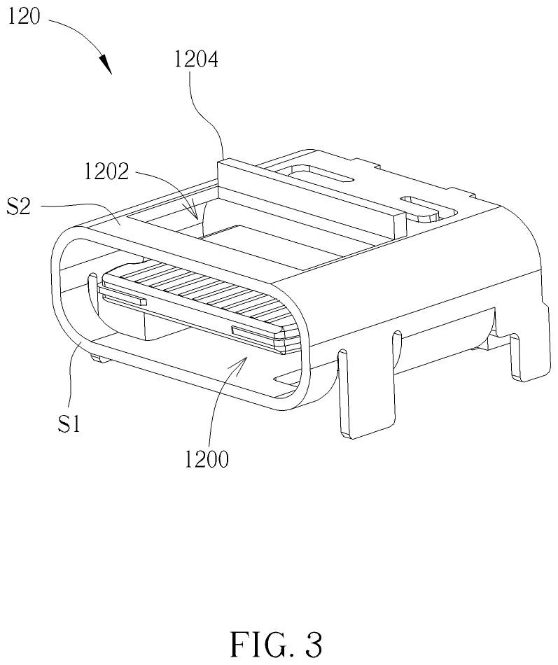

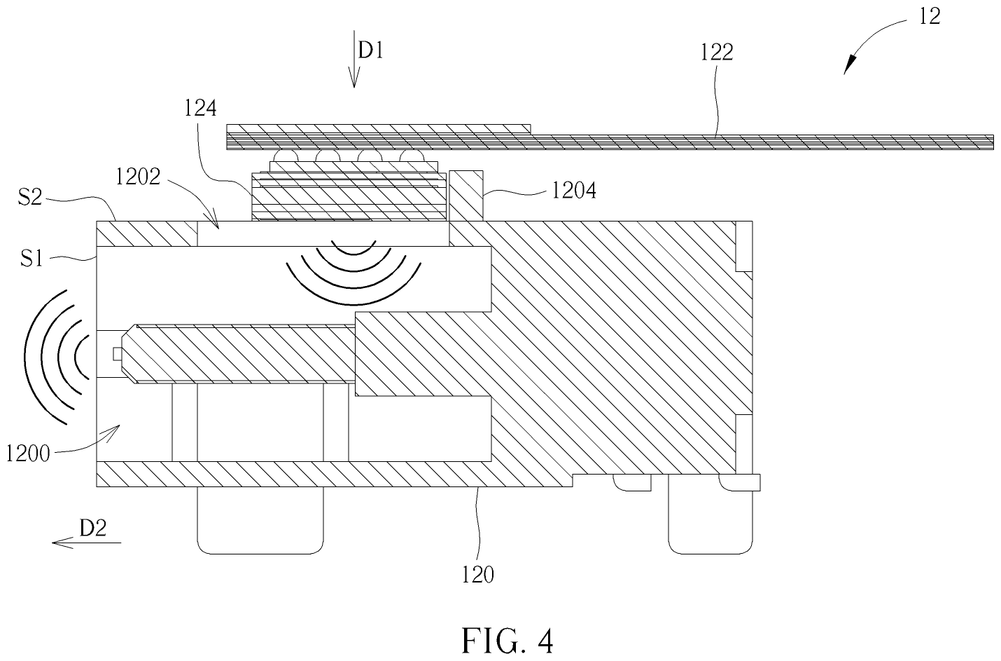

Referring to FIGS. 1 to 4, FIG. 1 is a perspective view illustrating an electronic device 1 according to an embodiment of the invention, FIG. 2 is a perspective view illustrating a signal transceiving module 12 shown in FIG. 1, FIG. 3 is a perspective view illustrating a connector 120 shown in FIG. 2, and FIG. 4 is a sectional view illustrating the signal transceiving module 12 shown in FIG. 2 along line X-X.

As shown in FIGS. 1 to 4, the electronic device 1 comprises a casing 10 and a signal transceiving module 12. The electronic device may be a mobile phone, a notebook computer, a tablet computer or other electronic devise equipped with the signal transceiving module 12, and it depends on practical applications. It should be noted that the casing 10 shown in FIG. 1 is illustrated by dotted line for purpose of explanation only, and the casing 10 may be designed according to practical applications. In general, the electronic device 1 may be further equipped with some necessary hardware and software components for specific purposes, such as a processor, a display device, a memory, a power supply, applications, a communication module, etc., and it depends on practical applications.

The signal transceiving module 12 is disposed in the casing 10. As shown in in FIG. 2, the signal transceiving module 12 comprises a connector 120, a circuit board 122 and a signal transceiver 124. In this embodiment, the connector 120 may be, but is not limited to, a universal serial bus (USB) female connector. A USB male connector may be plugged into the USB female connector for signal transmission or charging. As shown in FIG. 3, the connector 120 has a connecting hole 1200 and a signal feed-in hole 1202. The connecting hole 1200 is formed on a first side S1 of the connector 120 and exposed from a side of the casing 10. The signal feed-in hole 1202 is formed on a second side S2 of the connector 120. The first side S1 is adjacent to the second side S2. For example, the first side may be a front side of the connector 120 and the second side S2 may be a top side or a bottom side of the connector 120. In other words, the connecting hole 1200 may be formed on the front side of the connector 120 and the signal feed-in hole 1202 may be formed on the top side or the bottom side of the connector 120.

As shown in FIGS. 2 and 4, the circuit board 122 is disposed at a side (e.g. top side) of the connector 120. In this embodiment, the circuit board 122 may be, but is not limited to, a flexible printed circuit board (FPC) or printed circuit board (PCB). The signal transceiver 124 is connected to the circuit board 122 and aligned with the signal feed-in hole 1202 of the connector 120, such that the signal transceiver 124 can transmit and receive signals through the signal feed-in hole 1202. In this embodiment, the signal transceiver 124 may be, but is not limited to, an antenna or radar (e.g. mmWave radra). In this embodiment, the circuit board 122 may be connected to a main circuit board (not shown) disposed in the casing 10, such that a power supply unit (e.g. battery, not shown) disposed in the casing 10 may supply power to the circuit board 122 through the main circuit board. Furthermore, the circuit board 122 may be fixed to the casing 10 by suitable structures or, alternatively, the signal transceiver 124 may be fixed to connector 120 by suitable structures, so as to position the signal transceiver 124 with respect to the connector 120.

As shown in FIG. 4, the signal transceiver 124 feeds signals into the connector 120 through the signal feed-in hole 1202 and the signals are radiated out of the connector 120 through the connecting hole 1200. In this embodiment, the signal transceiver 124 may feed signals into the connector 120 through the signal feed-in hole 1202 in a first direction D1 and the signals may be radiated out of the connector 120 through the connecting hole 1200 in a second direction D2, wherein the first direction D1 may be perpendicular to the second direction D2. Thus, when the connector 120 is not connected with other connectors, the signal transceiver 124 can transmit and receive signals through the signal feed-in hole 1202 and the connecting hole 1200 to perform specific functions (e.g. gesture control).

As shown in FIGS. 2 to 4, the connector 120 may further has a metal wall 1204 protruding from a side of the signal feed-in hole 1202, and the signal transceiver 124 may be disposed with respect to the metal wall 1204. In this embodiment, the casing of the connector 120 may be made of metal (e.g. aluminum) and the metal wall 1204 may be formed integrally with the casing of the connector 120. The metal wall 1204 is configured to reflect signals radiated from the signal transceiver 124 toward the connecting hole 1200, so as to improve the radiation direction of the signal transceiver 124. In this embodiment, the signal transceiver 124 may abut against the metal wall 1204 to position the signal transceiver 124 with respect to the connector 120.

As mentioned in the above, the invention integrates the signal transceiver (e.g. antenna, radar, etc.) onto the connector. The connector has the connecting hole and the signal feed-in hole, and the signal transceiver is aligned with the signal feed-in hole, such that the signal transceiver can feed signals into the connector through the signal feed-in hole and the signals can be radiated out of the connector through the connecting hole. Accordingly, the signal transceiver can be disposed at the space around the connector to avoid increasing the size of the electronic device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electronic device comprising:
a casing; and
a signal transceiving module disposed in the casing, the signal transceiving module comprising:
a connector having a connecting hole and a signal feed-in hole, the connecting hole being formed on a first side of the connector and exposed from a side of the casing, the signal feed-in hole being formed on a second side of the connector, the first side being adjacent to the second side;
a circuit board disposed at a side of the connector; and
a signal transceiver connected to the circuit board and aligned with the signal feed-in hole;
wherein the signal transceiver feeds signals into the connector through the signal feed-in hole and the signals are radiated out of the connector through the connecting hole.

2. The electronic device of claim 1, wherein the connector further has a metal wall protruding from a side of the signal feed-in hole, and the signal transceiver is disposed with respect to the metal wall.

3. The electronic device of claim 2, wherein the signal transceiver abuts against the metal wall.

4. The electronic device of claim 1, wherein the signal transceiver feeds signals into the connector through the signal feed-in hole in a first direction, the signals are radiated out of the connector through the connecting hole in a second direction, and the first direction is perpendicular to the second direction.

5. The electronic device of claim 1, wherein the signal transceiver is an antenna or radar.

6. The electronic device of claim 1, wherein the connector is a USB female connector.

7. A signal transceiving module comprising:
a connector having a connecting hole and a signal feed-in hole, the connecting hole being formed on a first side of the connector, the signal feed-in hole being formed on a second side of the connector, the first side being adjacent to the second side;
a circuit board disposed at a side of the connector; and
a signal transceiver connected to the circuit board and aligned with the signal feed-in hole;
wherein the signal transceiver feeds signals into the connector through the signal feed-in hole and the signals are radiated out of the connector through the connecting hole.

8. The signal transceiving module of claim 7, wherein the connector further has a metal wall protruding from a side of the signal feed-in hole, and the signal transceiver is disposed with respect to the metal wall.

9. The signal transceiving module of claim 8, wherein the signal transceiver abuts against the metal wall.

10. The signal transceiving module of claim 7, wherein the signal transceiver feeds signals into the connector through the signal feed-in hole in a first direction, the signals are radiated out of the connector through the connecting hole in a second direction, and the first direction is perpendicular to the second direction.

11. The signal transceiving module of claim 7, wherein the signal transceiver is an antenna or radar.

12. The signal transceiving module of claim 7, wherein the connector is a USB female connector.
